(19) United States
(12) Patent Application Publication
(10) Pub. No.: US 2024/0069131 A1
(43) Pub. Date: Feb. 29, 2024

(54) Communication Method and Communication Apparatus for MRI Device

(71) Applicant: Siemens Healthcare GmbH, Erlangen (DE)

(72) Inventors: Jia Lin He, Shenzhen (CN); JianMin Wang, Shenzhen (CN); Jian Hong Liu, Shenzhen (CN); Li Chen Zhu, Shenzhen (CN)

(73) Assignee: Siemens Healthcare GmbH, Erlangen (DE)

(21) Appl. No.: 18/240,498

(22) Filed: Aug. 31, 2023

(30) Foreign Application Priority Data
Aug. 31, 2022 (CN) 202211053133.6

(51) Int. Cl. G01R 33/36; G01R 33/00

(52) U.S. Cl. CPC G01R 33/3692; G01R 33/0023

(57) ABSTRACT

The present disclosure relates to MRI device communications. The communications comprise: acquiring a received signal from a transmitting end, the received signal comprising multiple data symbols and multiple training symbol sets, each training symbol set comprising a first preset number of training symbols, with two adjacent training symbol sets of the multiple training symbol sets being spaced apart by a second preset number of the data symbols; extracting the first preset number of symbols from the received signal at intervals of the second preset number of symbols, to obtain a third preset number of symbols as a candidate training sequence; determining whether the candidate training sequence comprises the multiple training symbol sets; and in response to a determination that the candidate training sequence comprises the multiple training symbol sets, determining at least one of synchronization information and channel estimation information of the received signal.

### CROSS-REFERENCE TO RELATED APPLICATIONS

The present application claims priority to and the benefit of China patent application no. CN 202211053133.6, filed on Aug. 31, 2022, the contents of which are incorporated herein by reference in their entirety.

### TECHNICAL FIELD

The present disclosure relates to the technical field of medical equipment and communications and, in particular, to a communication method and communication apparatus for an MRI device, as well as an MRI device, an electronic device, a computer-readable storage medium, and a computer program product.

### BACKGROUND

Using the principle of nuclear magnetic resonance, based on different attenuations of released energy in the internal structure environment of different substances a magnetic resonance imaging (MRI) device obtains the types and positions of atomic nuclei of these substances by externally applying gradient magnetic fields and monitoring emitted electromagnetic waves.

Generally, it is necessary to perform data communications (e.g. data transmission and data receiving) between a portable MR wireless component of an MRI device (e.g. an ECG device, earphones and microphone, etc.) and the MRI device (e.g. coil assembly). However, problems such as the multi-path effect in the transmission channel will cause serious distortion of the received signal, making it impossible to accurately restore the signal transmitted by the transmitting end. Communication methods in the related art have problems such as an inability to accurately synchronize signals and an inability to learn the channel response state in real time, resulting in reduced accuracy and reliability of signal transmissions.

### SUMMARY

In view of the above, a first aspect of the present disclosure proposes a communication method for an MRI device. The communication method comprises: acquiring a received signal from a transmitting end, the received signal comprising multiple data symbols and multiple training symbol sets, each training symbol set comprising a first preset number of training symbols, with two adjacent training symbol sets of the multiple training symbol sets being spaced apart by a second preset number of the data symbols; extracting the first preset number of symbols from the received signal at intervals of the second preset number of symbols, to obtain a third preset number of symbols as a candidate training sequence; determining whether the candidate training sequence comprises the multiple training symbol sets; and in response to a determination that the candidate training sequence comprises the multiple training symbol sets, determining at least one of synchronization information and channel estimation information of the received signal.

A second aspect of the present disclosure proposes a communication method for an MRI device. The communication method comprises: acquiring a sequence to be transmitted, the sequence to be transmitted comprising multiple data symbols; acquiring a training sequence comprising multiple training symbol sets, each training symbol set comprising a first preset number of training symbols; respectively inserting the multiple training symbol sets among the multiple data symbols of the sequence to be transmitted, such that two adjacent training symbol sets of the multiple training symbol sets are spaced apart by a second preset number of the data symbols; using the post-insertion sequence to be transmitted as a transmitted signal; and transmitting the transmitted signal to a receiving end.

A third aspect of the present disclosure proposes a communication apparatus for an MRI device. The communication apparatus comprises: an acquisition module, configured to acquire a received signal from a transmitting end, the received signal comprising multiple data symbols and multiple training symbol sets, each training symbol set comprising a first preset number of training symbols, and two adjacent training symbol sets of the multiple training symbol sets being spaced apart by a second preset number of the data symbols; an extraction module, configured to extract the first preset number of symbols from the received signal at intervals of the second preset number of symbols, to obtain a third preset number of symbols as a candidate training sequence; and a first determining module, configured to determine whether the candidate training sequence comprises the multiple training symbol sets; and a second determining module, configured to determine at least one of synchronization information and channel estimation information of the received signal, in response to a determination that the candidate training sequence comprises multiple training symbol sets.

A fourth aspect of the present disclosure proposes a communication apparatus for an MRI device. The communication apparatus comprises: a first acquisition module, configured to acquire a sequence to be transmitted, which comprises multiple data symbols; a second acquisition module, configured to acquire a training sequence comprising multiple training symbol sets, each training symbol set comprising a first preset number of training symbols; an insertion module, configured to respectively insert the multiple training symbol sets among the multiple data symbols of the sequence to be transmitted, such that two adjacent training symbol sets of the multiple training symbol sets are spaced apart by a second preset number of the data symbols; a using module, configured to use the post-insertion sequence to be transmitted as a transmitted signal; and a transmitting module, configured to transmit the transmitted signal to a receiving end.

A fifth aspect of the present disclosure proposes an MRI device. The MRI device comprises at least one of a transmitting end and a receiving end, wherein the receiving end comprises: at least one first processor; and a first memory in communicative connection with the at least one first processor, wherein the first memory stores a first computer program which, when executed by the at least one first processor, realizes the communication method according to the first aspect of the present disclosure, and wherein the transmitting end comprises: at least one second processor; and a second memory in communicative connection with the at least one second processor, wherein the second memory stores a second computer program which, when executed by the at least one second processor, realizes the communication method according to the second aspect of the present disclosure.

A sixth aspect of the present disclosure proposes an electronic device, comprising: a memory, a processor, and a computer program stored on the memory, wherein the processor is configured to execute the computer program to realize steps of the communication method according to the first aspect of the present disclosure or steps of the communication method according to the second aspect of the present disclosure.

A seventh aspect of the present disclosure proposes a non-transitory computer-readable storage medium storing a computer program, wherein the computer program, when executed by a processor, realizes the communication method according to the first aspect of the present disclosure or the communication method according to the second aspect of the present disclosure.

An eighth aspect of the present disclosure proposes a computer program product comprising a computer program, wherein the computer program, when executed by a processor, realizes the communication method according to the first aspect of the present disclosure or the communication method according to the second aspect of the present disclosure.

According to one or more embodiments of the present disclosure, as a result of inserting a training sequence at intervals among multiple data symbols of the transmitted signal, the training sequence extracted at the receiving end can reflect the channel response and synchronize signals in real time, so as to perform signal synchronization and channel estimation simply and efficiently in real time, thereby increasing the accuracy and reliability of signal transmissions.

### BRIEF DESCRIPTION OF THE DRAWINGS

Embodiments of the present invention are described in detail below with reference to the accompanying drawings, to give those skilled in the art a clearer understanding of the abovementioned and other features and advantages of the present invention. Drawings:

FIG. 1 is a flow chart of an example communication method for an MRI device according to embodiments of the present disclosure.

FIG. 2 is a schematic diagram of an example training sequence, an example sequence to be transmitted, an example transmitted signal, and an example candidate training sequence according to embodiments of the present disclosure.

FIG. 3 is a flow chart of an example communication method for an MRI device according to other embodiments of the present disclosure.

FIG. 4 is a flow chart of a portion of the steps of the example communication method in FIG. 3.

FIG. 5a is a schematic diagram of an example result of cross-correlation of a candidate training sequence and an ideal training sequence according to embodiments of the present disclosure.

FIG. 5b is an enlarged diagram of the vicinity of a correlation peak in FIG. 5a.

FIG. 6 is a schematic block diagram of an example communication apparatus for an MRI device according to embodiments of the present disclosure.

FIG. 7 is a schematic block diagram of an example communication apparatus for an MRI device according to other embodiments of the present disclosure.

FIG. 8 shows an exemplary configuration of an example electronic device that may be used to implement the methods described herein.

### DETAILED DESCRIPTION OF THE DISCLOSURE

Generally, it is necessary to perform data communications (e.g. data transmission and data receiving) between a portable MR wireless component of an MRI device (e.g. an ECG device, earphones and microphone, etc.) and the MRI device (e.g. coil assembly). However, problems such as the multi-path effect in the transmission channel will cause serious distortion of the transmitted signal.

The applicant has noticed that in the related art, it is generally necessary to use a complex method to synchronize signals at two ends and adjust received signals. For example, in a cellular mobile wireless communication (e.g. 4G LTE) system, signals of the transmitting end and receiving end can be synchronized by means of a primary synchronization signal (PSS) and a secondary synchronization signal (SSS). However, although the PSS has good autocorrelation and cross-correlation, the synchronization effect is only good in the frequency domain. Similarly, the time domain synchronization of the SSS is not good, and sometimes it may even be impossible to achieve a correlation peak. Clearly, the PSS and SSS are not suitable for MRI devices, because MRI devices need to avoid, as much as possible, performing Fast-Fourier Transforms (FFTs) and thus occupying computing resources. As another example, signals of the transmitting end and receiving end may also be synchronized by leading data (e.g. rotational and non-rotational data) identification. Specifically, when the system is powered on and starts, the transmitting end transmits leading data comprising rotational and non-rotational data multiple times, and the receiving end needs to process the received leading data by a complex mechanism to identify timestamps between the rotational and non-rotational data. However, this method is very complex and has low synchronization efficiency. As another example, it is also possible to synchronize signals of the transmitting end and receiving end by a training sequence, and use an equalization filter to adjust the received signals. Specifically, the transmitting end transmits a training sequence after transmitting leading data and before user data. The receiving end uses the received training sequence to synchronize the signals and adjust parameters of the equalization filter. However, the abovementioned method is unable to acquire a channel response in real time, and only has a certain effect when the change in signal response is not fast, so it is not suitable for situations where the receiving end loses the training sequence or the signal response changes very quickly during signal transmission.

Based on the abovementioned technical problems, the applicant has found through in-depth research that for MRI applications, all of the wireless components are located in a copper shielded room, so interference from other devices is low. However, communication in an MRI device needs to ensure that interference arising at the magnetic resonance frequency due to signal transmission is low. In addition, in each communication, there is generally only one transmitting device and one receiving device, and the data transmission capacities of all components are predefined. Thus, the present disclosure proposes an effective communication method for an MRI device based on synchronous signal transmission.

In the present disclosure, a training sequence is inserted at intervals among multiple data symbols of a transmitted signal so that the training sequence extracted at the receiving end can reflect (i.e. indicate) the channel response and synchronize signals in real time, so as to perform signal synchronization and channel estimation simply and efficiently in real time, thereby increasing the accuracy and reliability of signal transmission. The communication method with the abovementioned advantages makes it unnecessary to establish an auxiliary communication path between the transmitting end and the receiving end (e.g. by a handshake between the transmitting end and receiving end), and can still perform signal synchronization and channel estimation (e.g. establish/adjust parameters of automatic gain control (AGC) and an equalization filter) if the connection between the transmitting end and receiving end is interrupted or the channel characteristics change significantly, without any need to establish a connection with the transmitting end.

Processing of the training sequence by the communication method according to the present disclosure is performed in the time domain with no need to use e.g. a field programmable gate array (FPGA), etc. to perform a FFT, so the method is suitable for various communication scenarios, particularly wireless communication scenarios in which power consumption needs to be avoided as much as possible.

As used herein, “symbol” means data resulting from channel encoding and modulation, and is an identification unit used when modulating/demodulating. One symbol may comprise at least one bit.

As used herein, a “cross-correlation operation” means the indefinite integral of the product of the complex conjugate and reverse translation of two functions respectively. The result of the cross-correlation operation can reflect the similarity between two signals.

As used herein, “correlation peak” is a sharp rising part appearing in the result of the cross-correlation operation. If there is a correlation peak in the result of the cross-correlation operation, this shows that there is similarity between the two signals, e.g. the two signals are the same or similar.

Exemplary embodiments of the present disclosure are described in detail below with reference to the drawings.

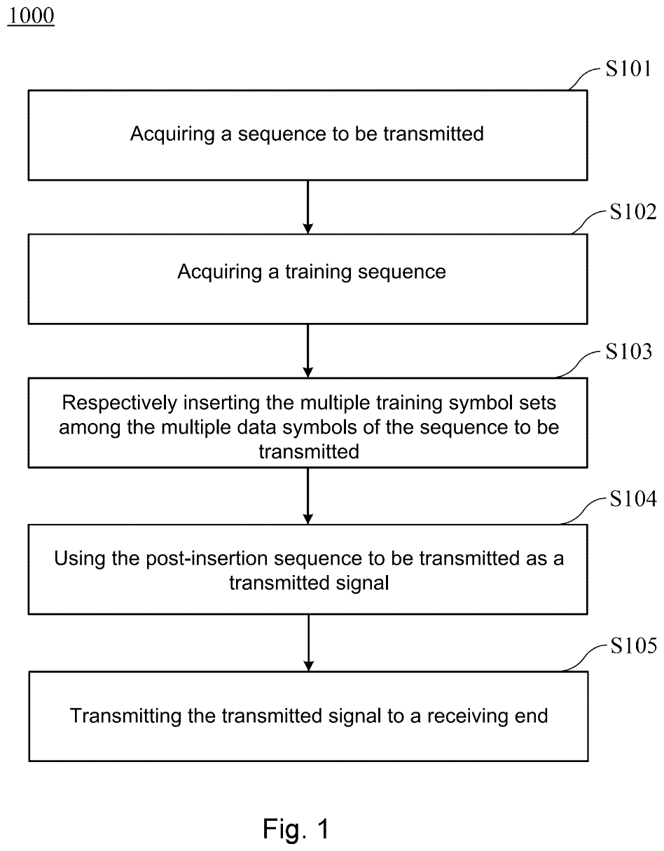

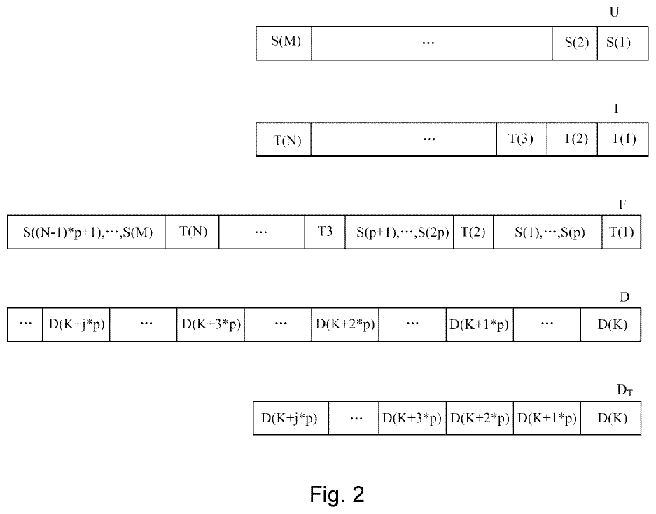

FIG. 1 is a flow chart of an example communication method 1000 for an MRI device according to embodiments of the present disclosure; FIG. 2 is a schematic diagram of a training sequence, a sequence to be transmitted, a transmitted signal and a candidate training sequence according to embodiments of the present disclosure. The steps of the communication method 1000 are described below with reference to FIGS. 1 and 2.

The communication method 1000 in FIG. 1 is implemented at a transmitting end of the MRI device. The transmitting end of the MRI device may be a portable MR wireless device of the MRI device (e.g. an electrocardiogram (ECG) device, earphones and microphone, etc.), or may be the MRI device itself, etc. As shown in FIG. 1, the communication method 1000 may comprise: step S101, acquiring a sequence to be transmitted, the sequence to be transmitted comprising multiple data symbols; step S102, acquiring a training sequence, the training sequence comprising multiple training symbol sets, each training symbol set comprising a first preset number of training symbols; step S103, respectively inserting the multiple training symbol sets among the multiple data symbols of the sequence to be transmitted, such that two adjacent training symbol sets of the multiple training symbol sets are spaced apart by a second preset number of data symbols; step S104, using the post-insertion sequence to be transmitted as a transmitted signal; and step S105, transmitting the transmitted signal to a receiving end.

In step S101, a sequence to be transmitted is acquired.

The sequence to be transmitted comprises multiple data symbols. The sequence to be transmitted is a data sequence that the transmitting end originally needs to transmit to the receiving end. As shown in FIG. 2, the sequence to be sent U comprises multiple data symbols S(1), S(2), . . . , S(M).

In step S102, a training sequence is acquired.

The training sequence may comprise multiple training symbol sets, each training symbol set comprising a first preset number of training symbols. The first preset number may be set as any positive integer such as 1, 2, 3, etc., as required. As shown in FIG. 2, it is assumed that the first preset number is equal to 1. The training sequence T comprises multiple training symbol sets T(1), T(2), T(3), . . . , T(N), wherein each training symbol set comprises one training symbol.

In step S103, the multiple training symbol sets are respectively inserted among the multiple data symbols of the sequence to be transmitted, such that two adjacent training symbol sets of the multiple training symbol sets are spaced apart by a second preset number of data symbols.

That is to say, all of the multiple training symbol sets are successively inserted among the multiple data symbols in order, at intervals of the second preset number of data symbols. At this time, adjacent training symbol sets are spaced apart by the second preset number of data symbols, and similarly, adjacent groups of the second preset number of data symbols are spaced apart by one training symbol set. The second preset number may be set as any positive integer such as 1, 2, 3, etc., as required. As shown in FIG. 2, it is assumed that the second preset number is denoted p. The multiple training symbol sets T(1), T(2), . . . , T(N) of the training sequence T are respectively inserted among the multiple data symbols S(1), S(2), . . . , S(M) of the sequence to be transmitted U. At this time, adjacent training symbol sets are spaced apart by p data symbols; for example, training symbol sets T(1) and T(2) are spaced apart by p data symbols S(1), . . . , S(p); training symbol sets T(2) and T(3) are spaced apart by p data symbols S(p+1), . . . , S(2p); the other training symbol sets and data symbols are arranged in the same way, and the final training symbol set T(N) in the training sequence is inserted in front of the data symbol S((N−1)*p+1). It should be noted here that the first training symbol set T(1) of the training sequence T may be inserted in front of the multiple data symbols S(1), S(2), . . . , S(M) as shown in FIG. 2, or the first training symbol set T(1) of the training sequence T may be inserted in any position among the multiple data symbols S(1), S(2), . . . , S(M), and the present disclosure is not limited to these examples.

In step S104, the post-insertion sequence to be transmitted is used as a transmitted signal.

Taking FIG. 2 as an example, the post-insertion sequence to be transmitted F is used as the transmitted signal.

In step S105, the transmitted signal is transmitted to a receiving end.

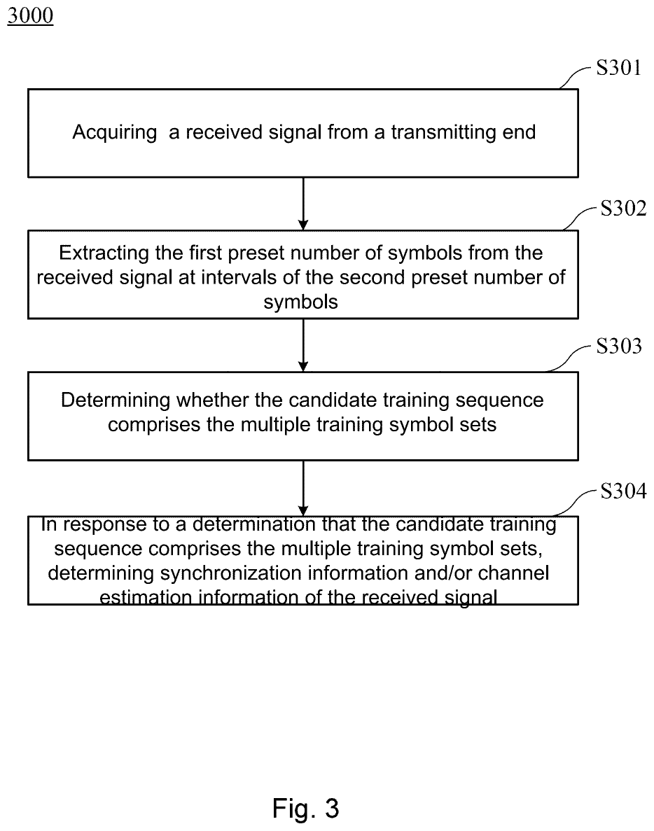

This transmitted signal forms a received signal after being received by the receiving end (this is described in detail below with reference to FIG. 3). Taking FIG. 2 as an example, after the transmitting end transmits the transmitted signal (i.e. the sequence to be transmitted F), a received signal D is received at the receiving end.

Inserting the training sequence at intervals among the multiple data symbols of the transmitted signal makes it easier to perform channel estimation and signal synchronization simply and effectively in real time at the receiving end, thereby increasing the accuracy and reliability of signal transmission.

In some embodiments, the training sequence is composed of random symbol numbers and has Dirac pulse correlation. As used herein, “Dirac pulse correlation” means that the result of the cross-correlation operation between two training sequences exhibits the pulse characteristic of the Dirac function. The training sequence may for example be white noise. As a result, the training sequence has good cross-correlation to facilitate signal synchronization and channel estimation at the receiving end.

In some embodiments, the length of the training sequence (i.e. the number of training symbols therein) may be set such that the effect of background noise on the training sequence is sufficiently small, and adjacent correlation peaks in the result of the cross-correlation operation thereof are spaced apart by a certain distance (e.g. a distance at which the adjacent correlation peaks can be distinguished from each other).

In some embodiments, step S103 of respectively inserting the multiple training symbol sets among the multiple data symbols of the sequence to be transmitted, such that two adjacent training symbol sets of the multiple training symbol sets are spaced apart by a second preset number of data symbols, may comprise: inserting a first training symbol set of the multiple training symbol sets in front of the multiple data symbols; and respectively inserting the training symbol sets other than the first training symbol set of the multiple training symbol sets among the multiple data symbols at intervals of a second preset number of data symbols. As shown in FIG. 2, the first training symbol T(1) in the training sequence T is inserted in front of the multiple data symbols S(1), S(2), . . . , S(M), and the other training symbols T(2), T(3), . . . , T(N) are respectively inserted among the multiple data symbols S(1), S(2), . . . , S(M) at intervals of p data symbols. Thus, at the receiving end, the first training symbol T(1) (i.e. the start position of the training sequence) can be conveniently used to determine the start position of the multiple data symbols, thereby facilitating signal synchronization and channel estimation at the receiving end.

FIG. 3 is a flow chart of a communication method 3000 for an MRI device according to embodiments of the present disclosure. The steps of the communication method 3000 are described below with reference to FIGS. 3 and 2. The communication method 3000 in FIG. 3 is implemented at a receiving end of the MRI device. The receiving end of the MRI device may be a portable MR wireless device of the MRI device (e.g. an ECG device, earphones and microphone, etc.), or may be the MRI device itself, etc. As shown in FIG. 3, the communication method 3000 may comprise: step S301, acquiring a received signal from a transmitting end, the received signal comprising multiple data symbols and multiple training symbol sets, each training symbol set comprising a first preset number of training symbols, with two adjacent training symbol sets of the multiple training symbol sets being spaced apart by a second preset number of data symbols; step S302, extracting the first preset number of symbols from the received signal at intervals of the second preset number of symbols, to obtain a third preset number of symbols as a candidate training sequence; step S303, determining whether the candidate training sequence comprises the multiple training symbol sets; and step S304, in response to a determination that the candidate training sequence comprises the multiple training symbol sets, determining at least one of synchronization information and channel estimation information of the received signal.

In step S301, a received signal from a transmitting end is acquired.

This transmitting end may be the transmitting end described in FIG. 1. The received signal comprises multiple data symbols and multiple training symbol sets, each training symbol set comprising a first preset number of training symbols, with two adjacent training symbol sets of the multiple training symbol sets being spaced apart by a second preset number of data symbols. The first preset number and second preset number are the same as the first preset number and second preset number described in FIG. 1. Since the received signal is obtained by receiving the transmitted signal transmitted by the transmitting end, the numbers and arrangement relationship of the data symbols and training symbols in the received signal at the receiving end are the same as the numbers and arrangement relationship of the data symbols and training symbols in the transmitted signal at the transmitting end. As shown in FIG. 2, just like the transmitted signal F at the transmitting end, the received signal D also comprises multiple data symbols and multiple training symbol sets. However, at the receiving end, it is not possible to learn the exact positions of the training symbols and data symbols in the received signal that is received. As shown in FIG. 2, the received signal D comprises the symbols D(K), . . . , D(K+1*p), . . . , D(K+2*p), . . . , D(K+3*p), . . . , D(K+j*p), . . . , etc., but it is not possible to determine the exact positions of the training symbols in the received signal, wherein p denotes the second preset number.

In some embodiments, the third preset number may be equal to the number of training symbols in the multiple training symbol sets. It is thus possible to ensure that all of the training symbols can be extracted. Alternatively, the third preset number may also be greater than the number of training symbols in the multiple training symbol sets, e.g. equal to a multiple of (e.g. 2, 3, 4 times, etc.) the number of training symbols in the multiple training symbol sets; in this way, the correlation between the candidate training sequence and a local training sequence can be increased.

As stated above, the features of the multiple training symbol sets are the same as the features of the training sequence described in FIG. 1. Specifically, the multiple training symbol sets are composed of random symbol numbers and have Dirac pulse correlation. As used herein, “Dirac pulse correlation” means that the result of the cross-correlation operation between two training sequences exhibits the pulse characteristic of the Dirac function. In some examples, the multiple training symbol sets may be white noise. As a result, the training sequence has good cross-correlation, to facilitate signal synchronization and channel estimation at the receiving end. In some examples, the length of the training sequence (i.e. the number of training symbols therein) may be set such that the effect of background noise on the training sequence is sufficiently small and two adjacent correlation peaks in the result of the cross-correlation operation thereof are spaced apart by a certain distance.

In step S302, the first preset number of symbols are extracted from the received signal at intervals of the second preset number of symbols, to obtain a third preset number of symbols as a candidate training sequence.

As stated above, the numbers and arrangement relationship of the data symbols and training symbols in the received signal at the receiving end are the same as the numbers and arrangement relationship of the data symbols and training symbols in the transmitted signal at the transmitting end. Thus, based on the arrangement relationship of the transmitted signal, the first preset number of symbols can be extracted from the received signal at intervals of the second preset number of symbols, to form a third preset number of symbols as a candidate training sequence. Taking FIG. 2 as an example, one symbol is extracted from the received signal at intervals of p symbols, and the third preset number of symbols extracted overall is the candidate training sequence DT, i.e. D(K), D(K+1*p), D(K+2*p), D(K+3*p), D(K+j*p). It should be noted here that it is possible to start extraction of a first symbol at any position in the received signal, and then extract one symbol at intervals of p symbols.

In step S303, a determination is made as to whether the candidate training sequence comprises the multiple training symbol sets.

Since the training sequence inserted at the transmitting end into the sequence to be transmitted is already known at the receiving end, an ideal training sequence associated with the training sequence at the transmitting end is stored locally at the receiving end. In some examples, the candidate training sequence and the ideal training sequence may be compared (e.g. by a cross-correlation operation) to determine whether the extracted candidate training sequence comprises the multiple training symbol sets; this is described in detail below.

In step S304, in response to a determination that the candidate training sequence comprises the multiple training symbol sets, at least one of synchronization information and channel estimation information of the received signal is determined.

That is to say, after determining that the extracted candidate training sequence comprises the multiple training symbol sets, it can be determined that the candidate training sequence is a received training sequence. Thus, signal synchronization and channel estimation operations can be performed on the basis of the received training sequence.

As a result of inserting a training sequence at intervals among multiple data symbols of the transmitted signal, the training sequence extracted at the receiving end can reflect the channel response and synchronize signals in real time, so as to perform signal synchronization and channel estimation simply and efficiently in real time, thereby increasing the accuracy and reliability of signal transmission.

In some embodiments, as stated above, the first training symbol set of the multiple training symbol sets may be located in front of the multiple data symbols. In this case, step S302 of extracting the first preset number of symbols from the received signal at intervals of the second preset number of symbols, to obtain a third preset number of symbols as a candidate training sequence, may comprise: extracting the first preset number of first symbols, starting from the first symbol in the received signal; after the first preset number of first symbols, extracting the first preset number of second symbols from the received signal at intervals of the second preset number of symbols; and using the first preset number of first symbols and the first preset number of second symbols as the third preset number of symbols. Taking FIG. 2 as an example, the first preset number of first symbols D(K) is extracted, starting from the first symbol in the received signal D, then after the first preset number of first symbols D(K), the first preset number of second symbols D(K+1*p), D(K+2*p), D(K+3*p), D(K+j*p) is extracted at intervals of the second preset number of symbols (p symbols), to form the candidate training sequence DT. In this way, the start position of the training sequence can be used to determine the start position of the multiple data symbols, thus facilitating signal synchronization and channel estimation.

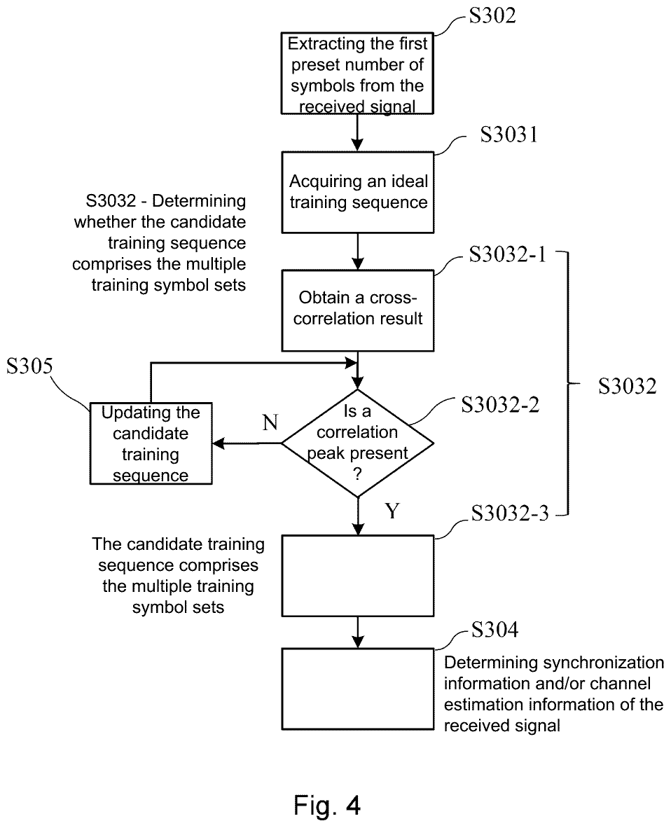

In some embodiments, as shown in FIG. 4, step S303 of determining whether the candidate training sequence comprises the multiple training symbol sets may comprise: step S3031, acquiring an ideal training sequence, which is associated with a training sequence corresponding to the multiple training symbol sets at the transmitting end; and step S3032, determining whether the candidate training sequence comprises the multiple training symbol sets on the basis of the candidate training sequence and the ideal training sequence. The ideal training sequence is a training sequence stored locally at the receiving end, and is related to the training sequence at the transmitting end (i.e. the training sequence at the transmitting end which the multiple training symbol sets in the received signal correspond to/come from). Specifically, the ideal training sequence may be the same as or similar to the training sequence at the transmitting end; for example, it may be any sequence for which the result of a cross-correlation operation with the training sequence at the transmitting end has a correlation peak. In the manner described above, it is possible to determine whether the candidate training sequence comprises the multiple training symbol sets in the received signal relatively accurately, thus facilitating subsequent signal synchronization and channel estimation operations.

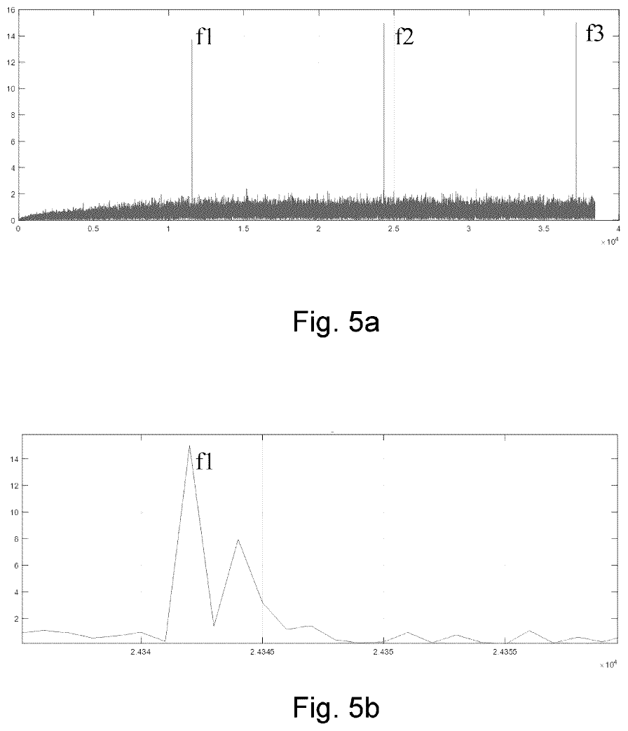

In some embodiments, as shown in FIG. 4, step S3032 of determining whether the candidate training sequence comprises the multiple training symbol sets on the basis of the candidate training sequence and the ideal training sequence may comprise: step S3032-1, subjecting the candidate training sequence and the ideal training sequence to a cross-correlation operation to obtain a cross-correlation result; step S3032-2, determining whether a correlation peak is present in the cross-correlation result; step S3032-3, in response to a determination that a correlation peak is present in the cross-correlation result, determining that the candidate training sequence comprises the multiple training symbol sets. Any peak detection method in the prior art may be used to determine whether a correlation peak is present in the cross-correlation result; details are not repeated here. Taking FIG. 2 as an example, the extracted candidate training sequence DT comprises D(K), D(K+1*p), D(K+2*p), D(K+3*p), D(K+j*p). The ideal training sequence at the receiving end is the same as the training sequence at the transmitting end, i.e. the training sequence T. At this time, the candidate training sequence DT and the ideal training sequence T may be subjected to a cross-correlation operation; for example, the conjugate matrix of the ideal training sequence T and the candidate training sequence DT are subjected to convolution, to obtain a cross-correlation result (as shown in FIG. 5a). As shown in FIG. 5a, a correlation peak in the cross-correlation result may have correlation information, comprising at least one of position information of the correlation peak, a maximum amplitude of the correlation peak, and a correlation value close to (e.g. within a threshold distance or value) the correlation peak. In the above embodiment, it is possible to determine whether the candidate training sequence comprises the multiple training symbol sets in the received signal relatively accurately according to the cross-correlation of the candidate training sequence and the ideal training sequence, thus facilitating subsequent signal synchronization and channel estimation operations.

In other embodiments, step S303 of determining whether the candidate training sequence comprises the multiple training symbol sets on the basis of the candidate training sequence and the ideal training sequence may also comprise: using a specific correlation algorithm to compute a correlation coefficient of the candidate training sequence and the ideal training sequence; and determining whether the candidate training sequence comprises the multiple training symbol sets on the basis of the correlation coefficient. The correlation algorithm may comprise the Chi-square algorithm, Pearson algorithm, etc.

In some embodiments, step S304 of determining at least one of synchronization information and channel estimation information of the received signal, in response to a determination that the candidate training sequence comprises the multiple training symbol sets, may comprise: acquiring correlation information of a correlation peak, the correlation information comprising position information of the correlation peak; and determining synchronization information of the received signal on the basis of the position information of the correlation peak. The synchronization information may for example comprise: start positions of multiple training symbol sets in the received signal, etc. In this way, signal synchronization can be performed on the basis of the abovementioned synchronization information. Since the position at which the correlation peak occurs in the cross-correlation result can indicate the start position of the training sequence in the received signal, the position information corresponding to the correlation peak can indicate the start positions of multiple training symbol sets in the received signal.

FIG. 5a shows the result of cross-correlation of the candidate training sequence and the ideal training sequence. The horizontal coordinates represent time, and the vertical coordinates represent correlation values. The cross-correlation result in FIG. 5a shows three correlation peaks f1, f2 and f3 corresponding to three candidate training sequences comprising multiple training symbol sets, the candidate training sequences being extracted from a received signal that is received continuously. Based on the position where each correlation peak occurs, the start position of the training sequence in the corresponding received signal can be learned.

In some embodiments, step S304 of determining at least one of synchronization information and channel estimation information of the received signal, in response to a determination that the candidate training sequence comprises the multiple training symbol sets, may comprise: acquiring correlation information of a correlation peak, the correlation information comprising at least one of a maximum amplitude of the correlation peak and a correlation value close to the correlation peak; and determining channel estimation information on the basis of at least one of the maximum amplitude of the correlation peak and the correlation value close to the correlation peak. The channel estimation information may comprise: at least one of received signal strength, channel response information, etc. This is because the maximum amplitude of the correlation peak is proportional to the received signal strength, and the correlation value close to the correlation peak (as shown in FIG. 5b) can be used to indicate the channel response situation, so the correlation information of the correlation peak can be used to determine channel estimation information.

In some embodiments, the communication method 3000 may further comprise adjusting the received signal on the basis of the channel estimation information. Specifically, for example, AGC parameters at the receiving end may be adjusted on the basis of the received signal strength, and the adjusted AGC may be used to adjust the received signal. As another example, it is possible to create an equalization filter (e.g. LMS, RLS, MLSE, etc.) or adjust equalization filter parameters on the basis of channel response information, and use the equalization filter to adjust the received signal, so as to eliminate inter-symbol interference (ISI) in the received signal caused for example by the multi-path effect; for example, to eliminate the correlation value close to the correlation peak shown in FIG. 5b. Thus, it can be ensured that the signal received at the receiving end can be free of distortion, to restore the transmitted signal transmitted by the transmitting end more accurately.

In some embodiments, the communication method 3000 may further comprise the following: in response to a determination that the candidate training sequence does not comprise the multiple training symbol sets: updating the candidate training sequence; and returning to perform determination of whether the candidate training sequence comprises the multiple training symbol sets (i.e. step S303). At this time, if the candidate training sequence is extracted incorrectly, the received signal may be subjected to extraction again to update the candidate training sequence, and the updated candidate training sequence may be used to determine whether the multiple training symbol sets are included, thus ensuring the correctness of candidate training sequence extraction.

In some embodiments, updating the candidate training sequence may comprise: extracting a symbol of the received signal located at the position following each of the third preset number of symbols, to serve as the candidate training sequence. For example, taking FIG. 2 as an example, upon determining that the previously extracted candidate training sequence D(K), D(K+1*p), D(K+2*p), D(K+3*p), D(K+j*p) does not comprise the multiple training symbol sets, the symbol at the position following each of the symbols in the previously extracted candidate training sequence may be extracted to form a new candidate training sequence, i.e. D(K+1), D(K+1+1*p), D(K+1+2*p), D(K+1+3*p), D(K+1+j*p). In this way, omission in extraction can be avoided, ensuring that a candidate training sequence comprising multiple training symbol sets can be extracted. Alternatively, it is also possible to extract a symbol of the received signal located at the nth position following each of the third preset number of symbols, to serve as the new candidate training sequence. Here, n may be set as any positive integer such as 2, 3 or 4 as required.

In other embodiments, as shown in FIG. 4, the communication method 3000 may also comprise: step S305, in response to a determination that no correlation peak is present in the cross-correlation result, updating the candidate training sequence; and returning to perform determination of whether a correlation peak is present in the cross-correlation result (i.e. step S3032-2). The specific manner in which the candidate training sequence is updated is the same as in the abovementioned step (i.e. updating the candidate training sequence in response to a determination that the candidate training sequence does not comprise the multiple training symbol sets), so details are not repeated here.

In some embodiments, the communication methods 1000 and 3000 described above may be used in scenarios involving communication between a single transmitting end and a single receiving end, or in scenarios involving communication between multiple transmitting ends and multiple receiving ends (e.g. MIMO). When the communication methods 1000 and 3000 described above are used in a MIMO scenario, each transmitting end may define a different training sequence (i.e. there is no correlation between the training sequences of the transmitting ends), and the training sequences defined by the multiple transmitting ends may be stored in the receiving ends as local training sequences. Just like the scenario of a single transmitting end and a single receiving end, in a MIMO scenario, a corresponding training sequence is inserted in a sequence to be transmitted at each transmitting end by performing the communication method 1000 described above to generate a transmitted signal, and synchronization information and/or channel estimation information of a received signal is determined at each receiving end by performing the communication method 3000 described above.

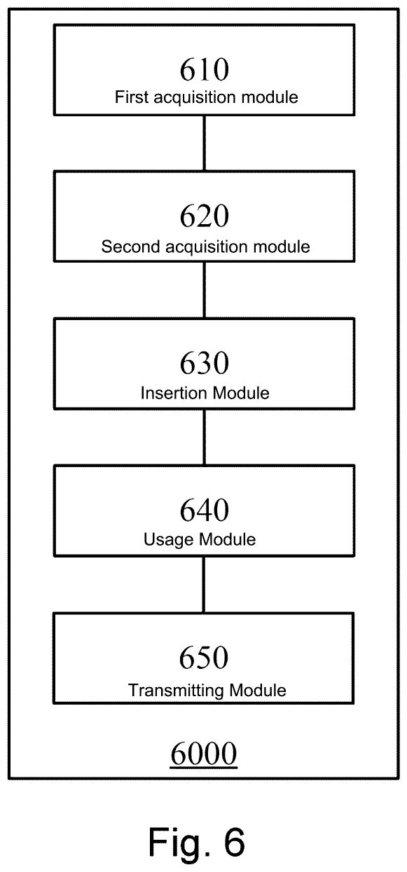

FIG. 6 is a schematic block diagram of a communication apparatus 6000 for an MRI device according to embodiments of the present disclosure. As shown in FIG. 6, the communication apparatus 6000 may comprise a first acquisition module (also referred to herein as first acquisition circuitry) 610, a second acquisition module (also referred to herein as second acquisition circuitry) 620, an insertion module (also referred to herein as insertion circuitry) 630, a using module (also referred to herein as a usage module or usage/using circuitry) 640, and a transmitting module (also referred to herein as transmitting circuitry) 650. The first acquisition module 610 is configured to acquire a sequence to be transmitted, which comprises multiple data symbols. The second acquisition module 620 is configured to acquire a training sequence comprising multiple training symbol sets, each training symbol set comprising a first preset number of training symbols. The insertion module 630 is configured to respectively insert the multiple training symbol sets among the multiple data symbols of the sequence to be transmitted, such that two adjacent training symbol sets of the multiple training symbol sets are spaced apart by a second preset number of data symbols. The using module 640 is configured to use the post-insertion sequence to be transmitted as a transmitted signal. The transmitting module 650 is configured to transmit the transmitted signal to a receiving end.

It should be understood that the modules of the apparatus 6000 shown in FIG. 6 may correspond to the steps in the method 1000 described with reference to FIG. 1. Thus, the operations, features, and advantages described above for the method 1000 likewise apply to the apparatus 6000 and the modules comprised therein. For conciseness, some operations, features, and advantages are not described again here.

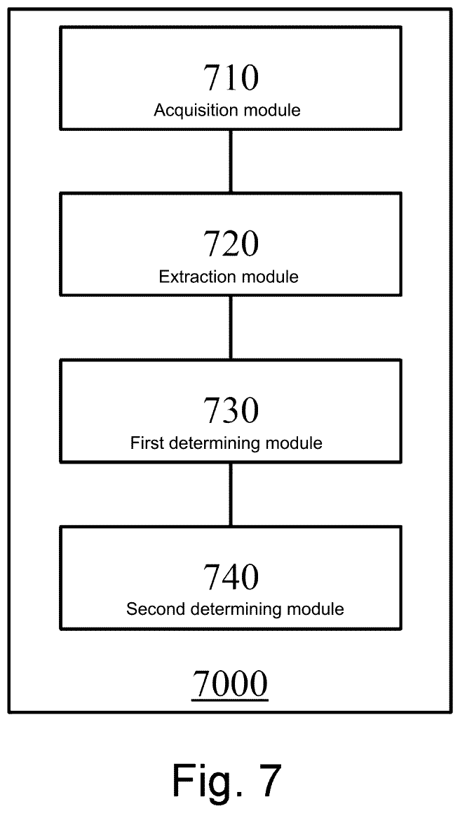

FIG. 7 is a schematic block diagram of a communication apparatus 7000 for an MRI device according to embodiments of the present disclosure. As shown in FIG. 7, the communication apparatus 7000 may comprise an acquisition module (also referred to herein as acquisition circuitry) 710, an extraction module (also referred to herein as extraction circuitry) 720, a first determining module (also referred to herein as first determining circuitry) 730, and a second determining module (also referred to herein as second determining circuitry) 740. The acquisition module 710 is configured to acquire a received signal from a transmitting end, the received signal comprising multiple data symbols and multiple training symbol sets, each training symbol set comprising a first preset number of training symbols, and two adjacent training symbol sets of the multiple training symbol sets being spaced apart by a second preset number of data symbols. The extraction module 720 is configured to extract the first preset number of symbols from the received signal at intervals of the second preset number of symbols, to obtain a third preset number of symbols as a candidate training sequence. The first determining module 730 is configured to determine whether the candidate training sequence comprises the multiple training symbol sets. The second determining module 740 is configured to determine at least one of synchronization information and channel estimation information of the received signal, in response to a determination that the candidate training sequence comprises the multiple training symbol sets.

It should be understood that the modules of the apparatus 7000 shown in FIG. 7 may correspond to the steps in the method 3000 described with reference to FIG. 3. Thus, the operations, features and advantages described above for the method 3000 likewise apply to the apparatus 7000 and the modules comprised therein. For conciseness, some operations, features and advantages are not described again here.

According to another aspect of the present disclosure, an MRI device is provided, comprising: at least one of a transmitting end and a receiving end. The receiving end comprises: at least one first processor; and a first memory in communicative connection with the at least one first processor, wherein the first memory stores a first computer program which, when executed by the at least one first processor, realizes the communication method 3000 described above. The transmitting end comprises: at least one second processor; and a second memory in communicative connection with the at least one second processor, wherein the second memory stores a second computer program which, when executed by the at least one second processor, realizes the communication method 1000 described above.

The features of the transmitting end and receiving end are respectively the same as the features of the transmitting end and receiving end described above with reference to FIGS. 1 and 3, so are not described again here.

According to another aspect of the present disclosure, an electronic device is provided, comprising: a memory, a processor, and a computer program stored on the memory, wherein the processor is configured to execute the computer program to realize the communication method 1000 or 3000 described above.

According to another aspect of the present disclosure, a non-transitory computer-readable storage medium storing a computer program is provided, wherein the computer program, when executed by a processor, realizes the communication method 1000 or 3000 described above.

According to another aspect of the present disclosure, a computer program product is provided, comprising a computer program which, when executed by a processor, realizes the communication method 1000 or 3000 described above.

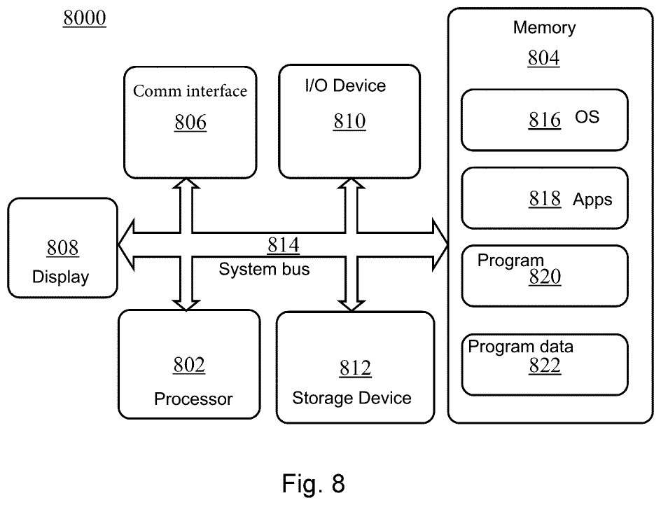

Illustrative examples of such a computer device, non-transitory computer-readable storage medium and computer program product are described below with reference to FIG. 8.

FIG. 8 shows an exemplary configuration of an electronic device 8000 that may be used to implement the methods described herein. The abovementioned communication apparatuses for an MRI device may also be completely or at least partially realized by the electronic device 8000 or a similar device or system.

The electronic device 8000 may be a variety of different types of device, e.g. a server of a service provider, a device associated with a client (e.g. a client device), a system on a chip, and/or any other suitable computer device or computing system. Examples of the electronic device 8000 include but are not limited to: a desktop computer, a server computer, a notebook computer or netbook computer, a mobile device (for example, a tablet computer, cellular or other wireless telephone (e.g. smartphone), notepad computer, mobile station), etc.

The electronic device 8000 may comprise the following, capable of communicating with each other for example by means of a system bus 814 or other suitable connection: at least one processor 802, a memory 804, (multiple) communication interface(s) 806, a display device 808, another input/output (I/O) device 810 and one or more large-capacity storage device 812.

The processor 802 may be a single processing unit or multiple processing units, and all of the processing units may comprise a single or multiple computing units or multiple cores. The processor 802 may be implemented as one or more microprocessor, microcomputer, microcontroller, digital signal processor, central processing unit, state machine, logic circuit and/or any device which controls signals on the basis of operating instructions. Besides other abilities, the processor 802 may be configured to acquire and execute computer-readable instructions stored in the memory 804, large-capacity storage device 812 or other computer-readable medium, such as program code of an operating system 816, program code of an application program 818, program code of another program 820, etc.

The memory 804 and large-capacity storage device 812 are examples of computer-readable storage media used to store instructions, which are executed by the processor 802 to implement the various functions described above. As an example, the memory 804 may generally comprise both a volatile memory and a non-volatile memory (e.g. RAM, ROM, etc.). In addition, the large-capacity storage device 812 may generally comprise a hard disk drive, solid state drive, removable media, including external and removable drives, memory cards, flash memory, floppy disks, optical disks (e.g. CD, DVD), storage arrays, network attached storage, storage area networks, etc. The memory 804 and large-capacity storage device 812 may both be collectively referred to as memory or computer-readable storage media herein, and may be non-transitory media capable of storing computer-readable, processor-executable program instructions as computer program code, which may be executed by the processor 802 as a specific device configured to implement the operations and functions described in the examples herein.

Multiple program modules may be stored on the large-capacity storage device 812. These programs comprise the operating system 816, one or more application programs 818, other program 820 and program data 822, and they may be loaded to the memory 804 for execution. Examples of such application programs or program modules may include, for example, computer program logic for realizing the following components/functions (e.g. computer program code or instructions): the apparatus 6000 (including the first acquisition module 610, second acquisition module 620, insertion module 630, using module 640 and transmitting module 650), the apparatus 7000 (including the acquisition module 710, extraction module 720, first determining module 730 and second determining module 740), the method 1000 (including any suitable steps of the method 1000), the method 3000 (including any suitable steps of the method 3000) and/or other embodiments described herein.

Although shown in FIG. 8 as being stored in the memory 804 of the computer device 8000, the modules 816, 818, 820 and 822 or parts thereof may be implemented using any form of computer-readable media that can be accessed by the computer device 8000. As used herein, “computer-readable media” include at least two types of computer-readable media: computer storage media and communication media.

Computer storage media include volatile and non-volatile, removable and non-removable media implemented by any method or technology used to store information such as computer-readable instructions, data structures, program modules or other data. Computer storage media include but are not limited to RAM, ROM, EEPROM, flash memory or other memory technologies, CD-ROM, digital versatile disks (DVD) or other optical storage means, magnetic cartridges, magnetic tape, magnetic disk storage means or other magnetic storage devices, or any other non-transmitting medium that can be used to store information for access by a computer device.

In contrast, communication media may specifically realize computer-readable instructions, data structures, program modules or other data in modulated data signals such as carriers or other transmission mechanisms. As defined herein, computer storage media do not include communication media.

The electronic device 8000 may further comprise one or more communication interface 806 for exchanging data with another device, for example by means of a network, direct connection, etc., as discussed above. Such a communication interface may be one or more of the following: any type of network interface (e.g. a network interface card (NIC)), wired or wireless (e.g. IEEE 802.11 wireless LAN (WLAN)) interface, Worldwide Interoperability for Microwave Access (Wi-MAX) interface, Ethernet interface, universal serial bus (USB) interface, cellular network interface, Bluetooth interface, near-field communication (NFC) interface, etc. The communication interface 806 can promote communication in various network and protocol types, including wired networks (e.g. LAN, electric cable, etc.) and wireless networks (e.g. WLAN, cellular, satellite, etc.), internet, etc. The communication interface 806 may also provide communication with an external storage apparatus (not shown) in, for example, a storage array, network attached storage, storage area network, etc.

In some examples, a display device 808 such as a monitor may be included, for displaying information and images to a user, e.g. displaying prompt information that motion correction is currently being performed, motion correction is complete, etc. Other I/O devices 810 may be devices that receive various inputs from the user and provide various outputs to the user, and may include a touch input device, gesture input device, camera, keyboard, remote controller, mouse, printer, audio input/output device, etc.

The above are merely embodiments of the present disclosure, which are not intended to limit it. Any amendments, equivalent substitutions or improvements, etc. made within the spirit and principles of the present disclosure shall be included in the scope of protection thereof.

To enable a clearer understanding of the technical features, objectives, and effects of the present disclosure, particular embodiments of the present disclosure are explained with reference to the accompanying drawings, in which identical labels indicate identical parts.

As used herein, “schematic” means “serving as an instance, example or illustration”. No drawing or embodiment described herein as “schematic” should be interpreted as being a more preferred or more advantageous technical solution.

To make the drawings appear uncluttered, only those parts relevant to the present disclosure are shown schematically in the drawings; they do not represent the actual structure thereof as a product. Furthermore, to make the drawings appear uncluttered for ease of understanding, in the case of components having the same structure or function in certain drawings, only one of these is drawn schematically, or only one is marked.

As used herein, “a” does not only mean “just this one”; it may also mean “more than one”. Some terms for which specific quantities are not defined may mean “one” or “multiple”. As used herein, “first” and “second” etc. are merely used to differentiate between parts, not to indicate their order or degree of importance, or any precondition of mutual existence, etc. The steps of any method disclosed herein do not need to be performed in the exact order disclosed, unless clearly stated.

The various components described herein may be referred to as “units” or “modules.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units or devices, as applicable and relevant, may alternatively be referred to herein as “circuitry,” “controllers,” “processors,” or “processing circuitry,” or alternatively as noted herein.

What is claimed is:

1. A method for providing communications for a magnetic resonance imaging (MRI) device, comprising:
acquiring a received signal from a transmitting end, the received signal comprising multiple data symbols and multiple training symbol sets,
wherein each training symbol set comprises a first preset number of training symbols, with two adjacent training symbol sets of the multiple training symbol sets being spaced apart by a second preset number of data symbols of the multiple data symbols;
extracting the first preset number of training symbols from the received signal at intervals of the second preset number of data symbols to obtain a third preset number of training symbols as a candidate training sequence;
determining whether the candidate training sequence comprises the multiple training symbol sets; and
in response to a determination that the candidate training sequence comprises the multiple training symbol sets, determining synchronization information and/or channel estimation information of the received signal.

2. The method as claimed in claim 1, wherein determining whether the candidate training sequence comprises the multiple training symbol sets comprises:
acquiring an ideal training sequence, which is associated with a training sequence corresponding to the multiple training symbol sets at the transmitting end; and
determining whether the candidate training sequence comprises the multiple training symbol sets based upon the candidate training sequence and the ideal training sequence.

3. The method as claimed in claim 2, wherein determining whether the candidate training sequence comprises the multiple training symbol sets based upon the candidate training sequence and the ideal training sequence comprises:
performing, on the candidate training sequence and the ideal training sequence, a cross-correlation operation to obtain a cross-correlation result;
determining whether a correlation peak is present in the cross-correlation result; and
in response to a determination that the correlation peak is present in the cross-correlation result, determining that the candidate training sequence comprises the multiple training symbol sets.

4. The method as claimed in claim 3, wherein determining the synchronization information and/or the channel estimation information of the received signal comprises:
acquiring correlation information comprising position information of the correlation peak; and
determining synchronization information of the received signal based upon the position information of the correlation peak.

5. The method as claimed in claim 3, wherein determining the synchronization information and/or the channel estimation information of the received signal comprises:
acquiring correlation information of the correlation peak, the correlation information comprising a maximum amplitude of the correlation peak and/or a correlation value identified with the correlation peak; and
determining the channel estimation information based upon the maximum amplitude of the correlation peak and/or the correlation value identified with the correlation peak.

6. The method as claimed in claim 1, further comprising:
adjusting the received signal based upon the channel estimation information.

7. The method as claimed in claim 1, further comprising:
in response to a determination that the candidate training sequence does not comprise the multiple training symbol sets, updating the candidate training sequence; and
repeating the determination of whether the candidate training sequence comprises the multiple training symbol sets.

8. The method as claimed in claim 7, wherein updating the candidate training sequence comprises:
extracting a symbol of the received signal located at a position following each of the third preset number of training symbols as the updated candidate training sequence.

9. The method as claimed in claim 1, wherein the third preset number is equal to, or equal to a multiple of, a number of training symbols in the multiple training symbol sets.

10. The method as claimed in claim 1, wherein the multiple training symbol sets comprise random symbol numbers and have Dirac pulse correlation.

11. A method for a magnetic resonance imaging (MRI) device, comprising:
acquiring a sequence to be transmitted, the sequence to be transmitted comprising multiple data symbols;
acquiring a training sequence comprising multiple training symbol sets,
wherein each training symbol set comprises a first preset number of training symbols;
respectively inserting the multiple training symbol sets from among the multiple data symbols of the sequence to be transmitted such that two adjacent training symbol sets of the multiple training symbol sets are spaced apart by a second preset number of data symbols of the multiple data symbols, thereby generating a post-insertion sequence;
using the post-insertion sequence to be transmitted as a transmitted signal; and
transmitting the transmitted signal to a receiving end.

12. The method as claimed in claim 11, wherein the training sequence comprises random symbol numbers and has Dirac pulse correlation.

13. An apparatus for a magnetic resonance imaging (MRI) device, comprising:
acquisition circuitry configured to acquire a received signal from a transmitting end, the received signal comprising multiple data symbols and multiple training symbol sets,
wherein each training symbol set comprises a first preset number of training symbols, with two adjacent training symbol sets of the multiple training symbol sets being spaced apart by a second preset number of data symbols of the multiple data symbols;
extraction circuitry configured to extract the first preset number of training symbols from the received signal at intervals of the second preset number of data symbols to obtain a third preset number of training symbols as a candidate training sequence;
first determining circuitry configured to determine whether the candidate training sequence comprises the multiple training symbol sets; and
second determining circuitry configured to, in response to a determination that the candidate training sequence comprises multiple training symbol sets, determine synchronization information and/or channel estimation information of the received signal.

14. An apparatus for a magnetic resonance imaging (MRI) device, comprising:
first acquisition circuitry configured to acquire a sequence to be transmitted, the sequence to be transmitted comprising multiple data symbols;
second acquisition circuitry configured to acquire a training sequence comprising multiple training symbol sets,
wherein each training symbol set comprises a first preset number of training symbols;
insertion circuitry configured to respectively insert the multiple training symbol sets among the multiple data symbols of the sequence to be transmitted such that two adjacent training symbol sets of the multiple training symbol sets are spaced apart by a second preset number of data symbols of the multiple data symbols, thereby generating a post-insertion sequence;
usage circuitry configured to use the post-insertion sequence to be transmitted as a transmitted signal; and
transmitting circuitry configured to transmit the transmitted signal to a receiving end.

15. A non-transitory computer-readable storage medium of a storing a computer program that, when executed by a processor identified with a magnetic resonance imaging (MRI) device, cause the MRI device to
acquire a received signal from a transmitting end, the received signal comprising multiple data symbols and multiple training symbol sets,
wherein each training symbol set comprises a first preset number of training symbols, with two adjacent training symbol sets of the multiple training symbol sets being spaced apart by a second preset number of data symbols of the multiple data symbols;
extract the first preset number of training symbols from the received signal at intervals of the second preset number of data symbols to obtain a third preset number of training symbols as a candidate training sequence;
determine whether the candidate training sequence comprises the multiple training symbol sets; and
in response to a determination that the candidate training sequence comprises the multiple training symbol sets, determine synchronization information and/or channel estimation information of the received signal.

16. A non-transitory computer-readable storage medium of a storing a computer program that, when executed by a processor identified with a magnetic resonance imaging (MRI) device, cause the MRI device to:
acquire a sequence to be transmitted, the sequence to be transmitted comprising multiple data symbols;
acquire a training sequence comprising multiple training symbol sets,
wherein each training symbol set comprises a first preset number of training symbols;
respectively insert the multiple training symbol sets from among the multiple data symbols of the sequence to be transmitted such that two adjacent training symbol sets of the multiple training symbol sets are spaced apart by a second preset number of data symbols of the multiple data symbols, thereby generating a post-insertion sequence;
use the post-insertion sequence to be transmitted as a transmitted signal; and
transmit the transmitted signal to a receiving end.
